(19) United States
(12) Patent Application Publication
(10) Pub. No.: US 2017/0023633 A1
(43) Pub. Date: Jan. 26, 2017

(54) TEST BOARD AND TEST SYSTEM INCLUDING THE SAME

(71) Applicant: SAMSUNG ELECTRONICS CO., LTD., Suwon-si (KR)

(72) Inventor: Ki-jae SONG, Cheonan-si (KR)

(21) Appl. No.: 15/164,926

(22) Filed: May 26, 2016

(30) Foreign Application Priority Data
Jul. 23, 2015 (KR) 10-2015-0104357

(51) Int. Cl. G01R 31/26; G01R 1/04

(52) U.S. Cl. CPC G01R 31/2637; G01R 1/0433

(57) ABSTRACT

A test board includes a plurality of power pads on a substrate. The power pads output a power supply voltage to a plurality of power terminals of a semiconductor device under test. The test board also includes a current limit circuit to limit current flowing through each of the power pads.

### CROSS-REFERENCE TO RELATED APPLICATION

Korean Patent Application No. 10-2015-0104357, filed on Jul. 23, 2015, and entitled, “Test Board and Test System Including the Same,” is incorporated by reference herein in its entirety.

### BACKGROUND

1. Field

One or more embodiments described herein relate to a test board and a test system including a test board.

2. Description of the Related Art

Increases in integration and processing speed have produced a decrease in the size of semiconductor devices and the size and pitch of the pins or balls used to mount those devices. This size reduction has made semiconductor devices susceptible to breaking during testing. If a semiconductor device breaks during testing, the device cannot be adequately tested for errors and thus a semiconductor chip of high quality cannot be fabricated. Moreover, even if the semiconductor device is able to pass a test, the device cannot be reliably used because it is broken.

### SUMMARY

In accordance with one or more embodiments, a test board includes a substrate; a plurality of power pads on the substrate, the power pads to output a power supply voltage to a plurality of power terminals of a semiconductor device under test; and a current limit circuit to limit a current flowing through each of the power pads.

The current limit circuit may provide the power supply voltage individually to the power pads through power lines respectively connected to the power pads, and limit current flowing through each of the power lines. The current limit circuit may include a plurality of current limiters connected to the power pads in a point-to-point manner.

The test board may include a plurality of ground pads on the substrate, the ground pads to output a ground voltage to the semiconductor device under test, wherein the current limit circuit is to limit a current flowing through each of the power pads and each of the ground pads. The current limit circuit may include a first current limit unit including a plurality of first current limiters respectively connected to the power pads; and a second current limit unit including a plurality of second current limiters respectively connected to the ground pads.

The test board may include a power plane in the substrate, wherein the current limit circuit is to electrically connect the power pads to the power plane. The power pads and the current limit circuit may be arranged on a first surface of the substrate. The power pads may be on a first surface of the substrate, the current limit circuit may be on a second surface different from the first surface of the substrate, and the current limit circuit and the power pads may be connected to each other through a through wiring line penetrating through the substrate.

The test board may include a connector to receive the power supply voltage from test equipment external to the test board and to provide the power supply voltage to the current limit circuit. The semiconductor device under test may be a semiconductor package including a semiconductor circuit, and at least one socket, onto which the semiconductor package is loaded, may be mounted on the test board.

In accordance with one or more other embodiments, a test system includes test equipment to test a semiconductor device under test; and a test board connected between the semiconductor device under test and the test equipment, wherein the test board includes a plurality of power pads electrically connected to the semiconductor device under test and wherein the test board is to individually provide at least one power supply voltage, which is supplied from the test equipment, to the power pads through a plurality of power lines and is to limit currents flowing through the power pads.

The test board may include a current control circuit which includes a plurality of current controllers respectively connected to the power pads. The test board may include a plurality of power lines respectively connecting the current controllers to the power pads in a point-to-point manner, wherein each of the current controllers is to limit a maximum current flowing through a corresponding one of the power lines.

The test system may include a connector to receive the at least one power supply voltage from the test equipment; and a power plane connected to the connector to provide the power supply voltage to each of the power pads through the current control circuit. The semiconductor device under test may be a semiconductor device having a high-speed data input/output terminal.

In accordance with one or more other embodiments, an apparatus includes a plurality of power pads to output a power supply voltage to a plurality of power terminals of a semiconductor device under test; and a current limit circuit to provide the power supply voltage individually to the power pads through a respective plurality of power lines connected to the power pads and to limit current flowing through each of the power lines. The current limit circuit may include a plurality of current limiters connected to the power pads in a point-to-point manner. The current limit circuit may include a first current limit unit including a plurality of first current limiters respectively connected to the power pads; and a second current limit unit including a plurality of second current limiters respectively connected to the ground pads.

### BRIEF DESCRIPTION OF THE DRAWINGS

Features will become apparent to those of skill in the art by describing in detail exemplary embodiments with reference to the attached drawings in which:

FIG. 1 illustrates an embodiment of a test board;

FIG. 2 illustrates another embodiment of a test board;

FIGS. 3A to 3C illustrate embodiments of test systems;

FIGS. 4 to 6 illustrate additional embodiments of test boards;

FIGS. 7A and 7B illustrates an additional embodiment of a test board;

FIGS. 8 to 10 illustrate additional embodiments of test boards;

FIG. 11 illustrates another embodiment of a test board;

FIG. 12 illustrates another embodiment of a test board; and

FIG. 13 illustrates an embodiment of a test apparatus.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. The embodiments may be combined to form additional embodiments.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terminology used herein is only for the purpose of describing specific embodiments and is not intended to limit the inventive concept. As used herein, the singular terms “a,” “an” and “the” are intended to include the plural forms as well, unless the context clearly indicates otherwise. It will be understood that the terms such as “comprises”, “comprising”, “includes”, “including”, “has”, and “having”, when used herein, specify the presence of stated features, but do not preclude the presence or addition of one or more other features. As used herein, the term “and/or” includes any and all combinations of one or more of the associated listed items.

Expressions such as “at least one of,” when preceding a list of elements, modify the entire list of elements and do not modify the individual elements of the list. It will be also understood that although the terms such as “first”, “second” and the like may be used herein to describe various features, these features should not be limited by these terms. These terms may be used only to distinguish one feature from another feature. It will be understood that when a first feature is referred to as being connected to or combined with a second feature in the following description, a third feature may be interposed between the first and second features.

When an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

Unless otherwise defined, all terms used herein, including technical and scientific terms, have the same meaning as generally understood by those of ordinary skill in the art. It will be understood that terms, such as those defined in generally used dictionaries, should be interpreted as having a meaning that is consistent with meanings understood in the context of the related art, and will not be interpreted in an idealized or overly formal sense unless expressly so defined herein.

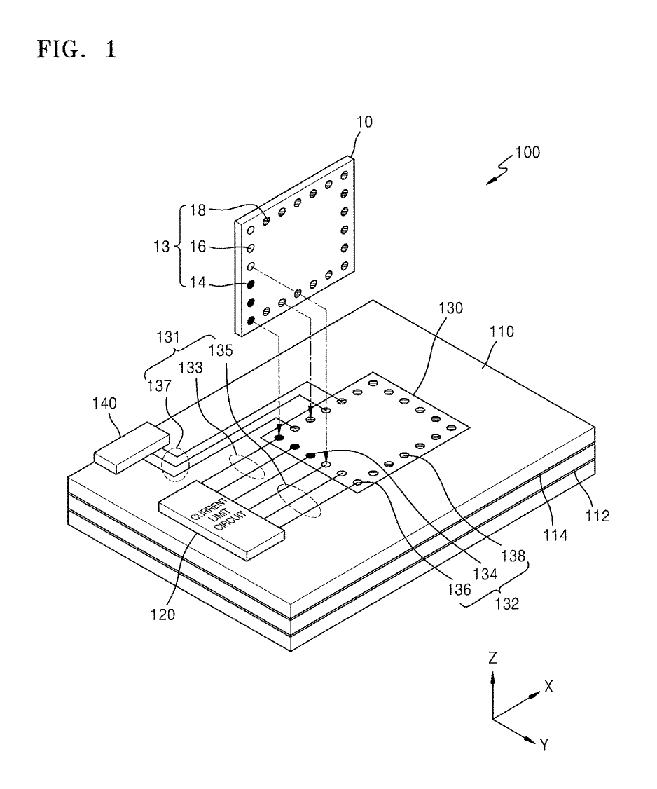

FIG. 1 illustrates an embodiment of a test board 100 which includes pads 132, wiring lines 131, and a current limit circuit 120 arranged on a substrate 110. The test board 100 may further include a connector 140. The test board 100 may be connected between test equipment and a semiconductor device 10 and thus may used to test the semiconductor device 10. In FIG. 1, one test board 100 is shown as being used to test the one semiconductor device under test 10 in FIG. 1. In another embodiment, a plurality of semiconductor devices 10 may be connected to the test board 100.

The semiconductor device under test 10 may be connected to the test equipment through the test board 100. The semiconductor device under test 10 may include a circuit device formed through a semiconductor fabrication process. The semiconductor device under test 10 may include a volatile memory device, e.g., a static RAM (SRAM), a dynamic RAM (DRAM), a synchronous DRAM (SDRAM), and the like. The semiconductor device under test 10 may include a non-volatile memory device, e.g., a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. The semiconductor device under test 10 may include a non-memory device, e.g., a microprocessor, a controller, a logic circuit, and the like. The semiconductor device under test 10 may include a system semiconductor device, e.g., a system large-scale integrated circuit (LSI) in which a logic circuit and a memory circuit are integrated. The semiconductor device under test 10 may include various semiconductor devices having high-speed data input/output terminals. The aforementioned types of semiconductor devices are only examples of the devices which may be tested in accordance with the embodiments described herein.

For example, the semiconductor device under test 10 may be a wafer-level semiconductor device which is in a stage before performing a packaging process after formation of a circuit device through a semiconductor fabrication process. The semiconductor device under test 10 may be a semiconductor die obtained by dividing a semiconductor wafer, in which a semiconductor circuit is formed, through a dicing process. In this case, the test board 100 may be a probe card used to test the semiconductor die, and the pads 132 of the test board 100 may have needle shapes.

The semiconductor device under test 10 may be a semiconductor package obtained by packaging a semiconductor die in which a semiconductor circuit is formed. The semiconductor device under test 10 may have a form of an integrated package obtained by integrating a plurality of homogeneous or heterogeneous semiconductor packages into one package. In this case, the test board 100 may be a hi-fix board. The semiconductor package may be loaded onto a socket and terminals 13 of the semiconductor package may be electrically connected to the pads 132 of the test board 100 through contacts in the socket.

The semiconductor device under test 10 includes the plurality of terminals 13 to be connected to the test board 100. The terminals 13 may include, for example, at least one power terminal 14, at least one ground (or reference) terminal 16, and at least one data terminal 18 according to signals transmitted through the terminals. A power supply voltage of the semiconductor device under test 10 may be applied through the power terminal 14. A ground voltage of the semiconductor device under test 10 may be applied through the ground terminal 16. The power supply voltage may be referred to, for example, as VDD, VDD1, VDD2, or the like. The ground voltage may be referred to, for example, as VSS, VSS1, VSS2, GND, or the like.

Commands, addresses, input/output data, and or other forms of data or signals may be input to or output from the semiconductor device under test 10 through the data terminal 18. The semiconductor device under test 10 is shown as including the three power terminals 14, the three ground terminals 16, and the three data terminals 18. The number of the power terminals 14, ground terminals 16, and/or data terminals 18 and/or the total number of the terminals 13 may be different in another embodiment.

The terminals 13 may have various shapes based on, for example, the shape or type of the semiconductor device under test 10. For example, if the semiconductor device under test 10 is a semiconductor die, the terminals 13 may have shapes of contact pads. If the semiconductor device under test 10 is a semiconductor package, the terminals 13 may have various shapes, e.g., ball shapes, pad shapes, lead shapes, pin shapes, and the like, according to shape of the package.

The substrate 110 may include a connection region 130 for connection to the semiconductor device under test 10. The pads 132 corresponding to the terminals 13 of the semiconductor device under test 10 may be arranged in the connection region 130. The pads 132 may output the power supply voltage, the ground voltage, and/or data to the semiconductor device under test 10. The pads 132 may include power pads 134, ground pads 136, and data pads 138 according to the corresponding terminals 13.

As shown in FIG. 1, the semiconductor device under test 10 may be arranged directly on or in contiguity with the connection region 130. Thus, the power terminals 14, the ground terminals 16, and the data terminals 18 of the semiconductor device under test 10 may be electrically connected to the corresponding power pads 134, the corresponding ground pads 136, and the corresponding data pads 138 of the test board 100, respectively. In another embodiment, the semiconductor device under test 10 may be loaded onto a socket to be mounted on the connection region 130. The power terminals 14, the ground terminals 16, and the data terminals 18 of the semiconductor device under test 10 may be electrically connected to the corresponding power pads 134, the corresponding ground pads 136, and the corresponding data pads 138 of the test board 100 through contacts in the socket, respectively.

Wiring lines 131 may be arranged on the substrate 110. The wiring lines 131 may transmit the power supply voltage, the ground voltage, and/or data to the pads 132. The wiring lines 131 may include power lines 133, ground lines 135, and/or data lines 137 according to kinds of provided signals.

The power lines 133 and the ground lines 135 may electrically connect the power pads 134 and the ground pads 136 to a current limit circuit 120. The data lines 137 may connect a connector 140 and the data pads 138 to each other. The data lines 137 may be electrically connected only to the data pads 138 used to test the semiconductor device under test 10, rather than connected to all the data pads 138.

The wiring lines 131 in FIG. 1 are arranged on an upper surface of the substrate 110. In another example, the wiring lines 131 may be formed using at least one conductive layer selected from among conductive layers of the substrate 110. The wiring lines 131 may be electrically connected to the pads 132 on the upper surface of the substrate 110 using via contact plugs.

The current limit circuit 120 may adjust the amount of current output through the power pads 134 or the amount of current input through the ground pads 136. For example, for at least one pad of the power pads 134 and the ground pads 136, the current limit circuit 120 may limit the maximum amount of current flowing through each of the pads such that the amount of current flowing through each of the pads does not exceed a predetermined critical amount of current.

In an exemplary embodiment, the current limit circuit 120 may limit the amount of current flowing through each of the power pads 134. In another exemplary embodiment, the current limit circuit 120 may limit the amount of current flowing through each of the ground pads 136. In a further exemplary embodiment, the current limit circuit 120 may limit the amount of current flowing through each of the power pads 134 and the ground pads 136.

For this purpose, the current limit circuit 120 may include a plurality of current limiters connected to the power pads 134 and the ground pads 136. The plurality of current limiters may be connected to the power pads 134 or the ground pads 136 through the power lines 133 or the ground lines 137 in a point-to-point manner. The current limiters limit the amount of current flowing through the power lines 133 and the ground lines 137, while providing the power supply voltage or the ground voltage to each of the power pads 134 or the ground pads 136 through the power lines 133 or the ground lines 135. As a result, the amount of current flowing through each of the power pads 134 and the ground pads 136 may be limited.

The current limit circuit 120 may be realized, for example, as a semiconductor chip or module to be mounted on the test board 100. In FIG. 1, the test board 100 includes one current limit circuit 120. In one embodiment, the test board 100 may include a plurality of current limit circuits 120. In addition, in FIG. 1, one current limit circuit 120 is connected to the pads 132 in the one connection region 130. In another embodiment, one current limit circuit 120 may be connected to a plurality of semiconductor devices under test 10 or the plurality of current limit circuits 120 may be connected to one semiconductor device under test 10.

The substrate 110 may include a power plane 112 and a ground plane 114. The substrate 110 may include, for example, a printed circuit board. The substrate 110 may include a multilayer printed circuit board including a plurality of conductive layers interposed among a plurality of insulating layers. One conductive layer may include the power plane 112 and another conductive layer may include the ground plane 114.

The power plane 112 may be connected to the power pads 134. The ground plane 114 may be connected to the ground pads 136. The power plane 112 or the ground plane 114 may be electrically connected to the power pads 134 or the ground pads 136 through the current limit circuit 120. The power plane 112 may be connected to the current limit circuit 120 using a via contact plug penetrating through the insulating layers and the conductive layers between the power plane 112 and the current limit circuit 120. The ground plane 114 may be connected to the current limit circuit 120, for example, using a via contact plug penetrating through the insulating layers and the conductive layers between the ground plane 114 and the current limit circuit 120.

The test board 100 may further include the connector 140. A test apparatus creating a test sequence for testing the semiconductor device under test 10 and a power supply supplying the power supply voltage to the semiconductor device under test 10 may be connected to the connector 140. One integrated cable or a plurality of cables may be connected to the connector 140. Test board 100 may be mounted directly on a test header without the connector 140. The test header may be electrically connected to the test apparatus.

The connector 140 may receive the power supply voltage, the ground voltage, and/or data, and/or the connector 140 may provide the power supply voltage or the ground voltage, which is received, to the current limit circuit 120. In addition, the connector 140 may provide the received data to the data pads 138 through data lines 137.

As more highly integrated and higher-speed semiconductor devices are produced, the spacing between the terminals of the semiconductor devices (for example, spacing between solder balls of a semiconductor package) decreases. If the contact between the semiconductor device 10 and the connection region 130 of the test board 100 is unstable when a test for the semiconductor device under test 10 is performed, a large short current may be generated when the power terminals 14 and the ground terminals 16 of the semiconductor device are short-circuited. For example, since a high level of the power supply voltage may be applied for inspection when a test is performed, the terminals 13 of the semiconductor device under test 10 may be damaged due to the short current. Since the power terminals 14 and the ground terminals 16 are connected to each other through the power plane and the ground plane, the power terminals 14 and the ground terminals 16 may be damaged even when one of the power terminals 14 and one of the ground terminals 16 are short-circuited.

In accordance with one or more embodiments, the current limit circuit 120 limits the maximum amount of current flowing through each of the power pads 134 or the ground pads 136. As a result, the test board 100 may prevent generation of the large short current even when the power terminals 14 and the ground terminals 16 of the semiconductor device under test 10 are short-circuited. Damage to the power terminals 14 and the ground terminals 16 may therefore be prevented.

In addition, since the current limit circuit 120 limits the maximum amount of current flowing through each of the power pads 134 or the ground pads 136, the test board 100 may prevent generation of a high peak current in the semiconductor device under test 10. The test board 100 prevents a potential difference between the power supply voltage and the ground voltage from deviating from a margin of a driving voltage, and allows levels of the power supply voltage and the ground voltage to be stably maintained. As a result, test reliability may be improved.

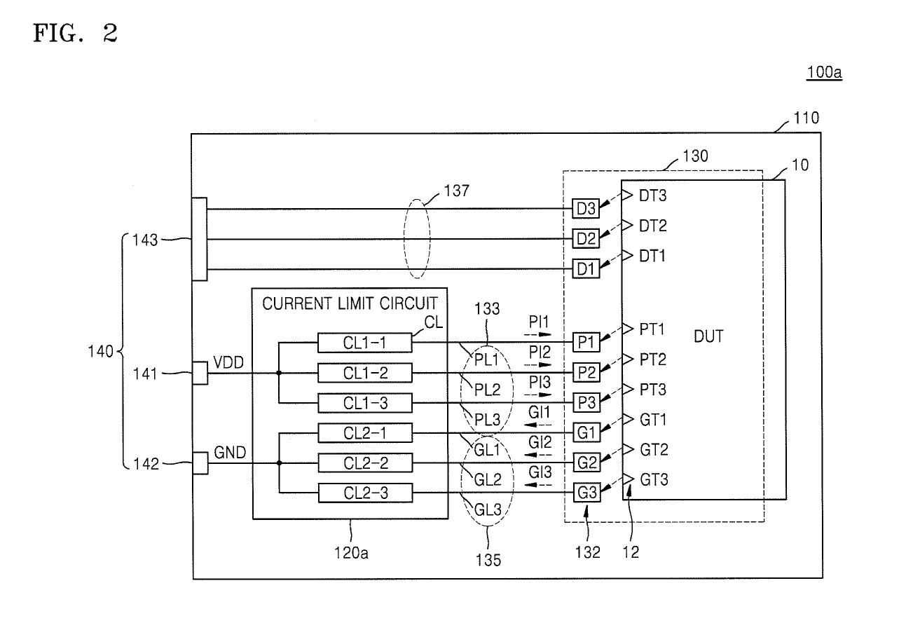

FIG. 2 illustrates another embodiment of a test board 100a which includes a current limit circuit 120a. Referring to FIG. 2, the test board 100a includes the plurality of pads 132, the current limit circuit 120a, the wiring lines 133, 135, 137, and the connector 140 arranged on the substrate 110.

The pads 132 may be arranged on the connection region 130 and electrically connected to the terminals 13 of the semiconductor device under test 10. The pads 132 may include power pads P1 to P3, ground pads G1 to G3, and data pads D1 to D3. The power pads P1 to P3, the ground pads G1 to G3, and the data pads D1 to D3 may be connected to power terminals PT1 to PT3, ground terminals GT1 to GT3, and data terminals DT1 to DT3 of the semiconductor device under test 10, respectively. In FIG. 2, the three power pads P1 to P3, the three ground pads G1 to G3, and the three data pads D1 to D3 are shown. Another embodiment may have a different number of the pads.

The connector 140 may include a power input port 141, a ground input port 142, and a data input/output port 143. The power input port 141 and the ground input port 142 may be connected to the current limit circuit 120a. A power supply voltage VDD applied through the power input port 141 and a ground voltage GND applied through the ground input port 142 may be provided to the current limit circuit 120a. In an exemplary embodiment, the power supply voltage VDD and the ground voltage GND may be provided to the current limit circuit 120a through a power plane 112 in FIG. 1 and a ground plane 114 in FIG. 1. The data input/output port 143 may be connected to the data pads D1 to D3 through the data lines 137. The data input/output port 143 may provide test data from an external test apparatus to the semiconductor device under test 10, and may provide result data output from the semiconductor device under test 10 to the external test apparatus.

The current limit circuit 120a may individually provide the power supply voltage VDD and the ground voltage GND, which are provided from the power input port 141 and the ground input port 142, to the power pads P1 to P3 and the ground pads G1 to G3 through the power lines 133 and the ground lines 135. The current limit circuit 120a may control amounts of current PI1 to PI3, GI1 to GI3 flowing through the power pads P1 to P3, and the ground pads G1 to G3.

The current limit circuit 120a may be an array of current limiters CL. The current limiters CL may include output current limiters CL1-1, CL1-2, CL1-3 and input current limiters CL2-1, CL2-2, CL2-3. The output current limiters CL1-1, CL1-2, CL1-3 may be operated based on the applied power supply voltage VD, and may limit amounts of output current PI1 to PI3 which are output from the power pads P1 to P3. The input current limiters CL2-1, CL2-2, CL2-3 may be operated based on the ground voltage GND and may limit amounts of input current GI1 to GI3 which are input to the ground pads G1 to G3.

The current limiters CL may be connected to the power pads P1 to P3 and the ground pads G1 to G3 through a plurality of power lines PL1 to PL3 and a plurality of ground lines GL1 to GL3 in a point-to-point manner. The current limiters CL may limit the amounts of current flowing through the power lines PL1 to PL3 and the ground lines GL1 to GL3, respectively. This may limit the amounts of output current PI1 to PI3, which are output from the power pads P1 to P3 and the amounts of input current GI1 to GI3, which are input to the plurality of ground pads G1 to G3, respectively. For example, the first output current limiter CL1-1 may limit the amount of the first output current PI1 flowing through the first power line PL1 and the first output pad P1. The first input current limiter CL2-1 may limit the amount of the first input current GI1 flowing through the first ground line GL1 and the first ground pad G1. Thus, the current limit circuit 120a may prevent a large amount of overcurrent from flowing through the power terminals PT1 to PT3 and the ground terminals GT1 to GT3 of the semiconductor device under test 10.

The current limit circuit 120a may also limit the total amount of current input to or output from the semiconductor device under test 10. Thus, the current limit circuit 120a may prevent a high peak current from being generated in the semiconductor device under test 10.

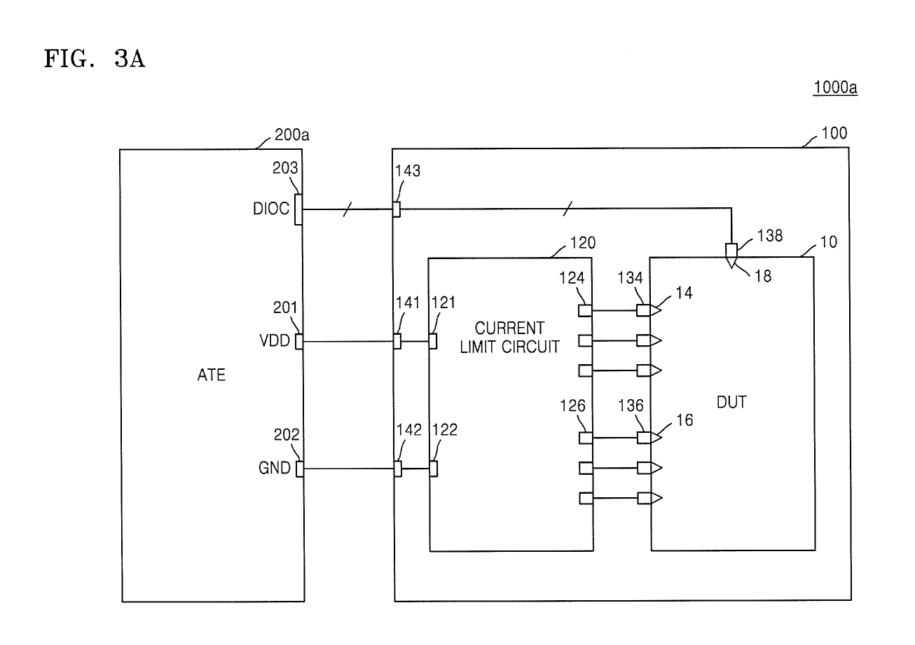

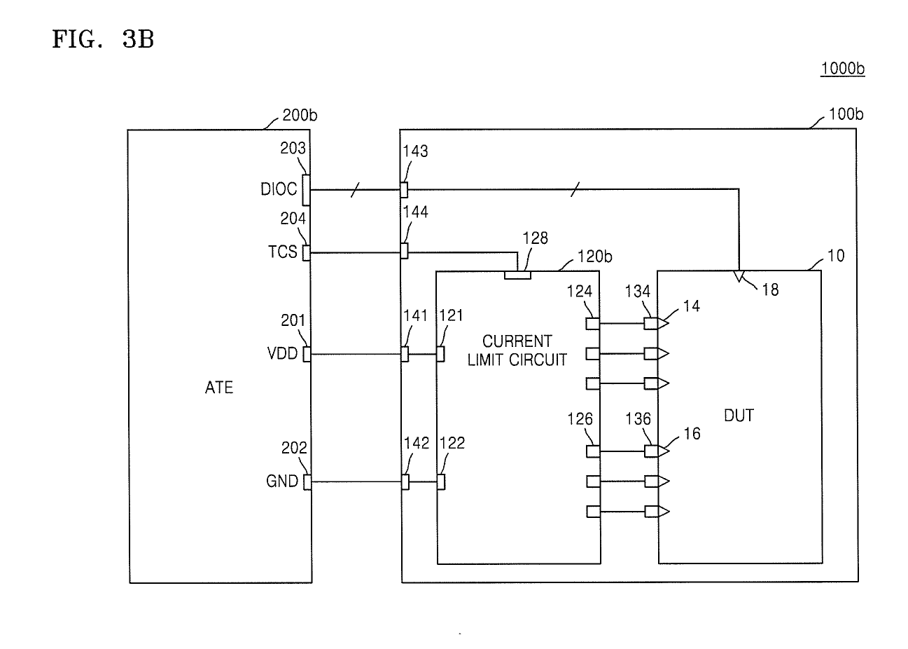

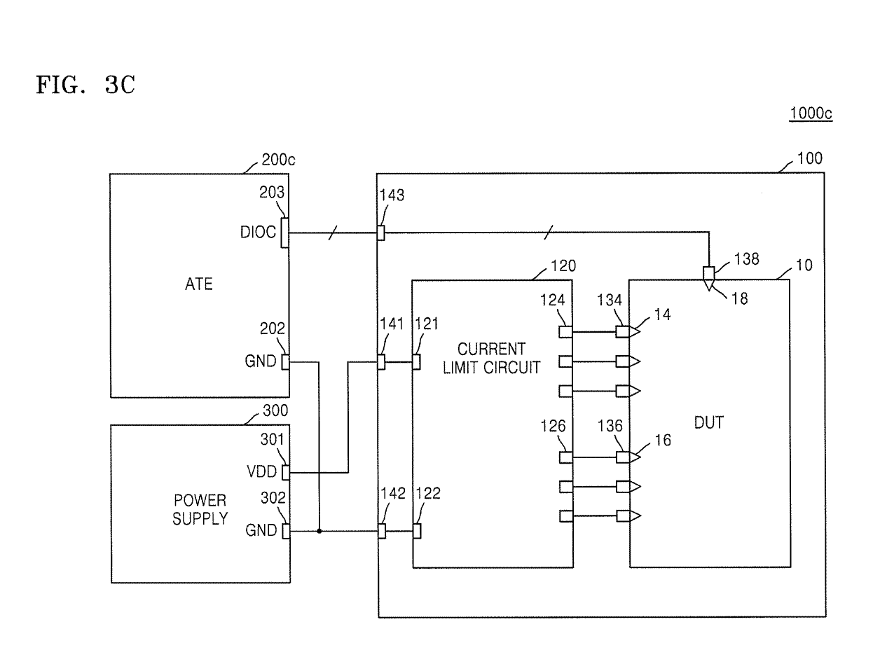

FIG. 3A illustrates an embodiment of test system 1000a which includes automatic test equipment 200a for testing the semiconductor device under test 10 and the test board 100 for connecting the semiconductor device under test 10 and the automatic test equipment 200a to each other.

The semiconductor device under test 10 includes the power terminal 14, the ground terminal 16, and the data terminal 18. The semiconductor device under test 10 may be, for example, any of the devices previously described.

The test board 100 is connected to the semiconductor device under test 10 and includes the current limit circuit 120. The test board 100 may include, for example, the test board 100a described with reference to FIG. 2 or any of the test boards described in the embodiments which follow. The test board 100 may include the power input port 141, the ground input port 142, and the data input/output port 143 to be connected to the automatic test equipment 200a. The power input port 141, the ground input port 142, and the data input/output port 143 may collectively form the connector 140 in FIG. 1.

The current limit circuit 120 may include a power input terminal 121 to which the power supply voltage is applied, a ground input terminal 122 connected to the automatic test equipment 200a and to which the ground voltage GND is applied, a plurality of power output terminals 124, and a plurality of ground (or reference) output terminals 126. The power output terminals 124 individually output the power supply voltage VDD to the power pads 134. The ground output terminals 126 individually output the ground voltage to the ground pads 134. The amount of current, which is input or output through each of the power output terminals 124 and the ground output terminals 126, may be limited.

The automatic test equipment 200a may provide a test sequence for testing the semiconductor device under test 10. The automatic test equipment 200a may include, for example, a power output channel 201, a ground channel 202, and a data input/output channel 203.

The power output channel 201 supplies the power supply voltage VDD through the power input port 141 of the test board 100. The power supply voltage from the automatic test equipment 200a is applied to the power input terminal 121 of the current limit circuit 120. The power output channel 201 may output a constant level of the power supply voltage VDD. The power output channel 201 may function as a power supply in terms of outputting a direct current voltage. In an exemplary embodiment, the power output channel 201 may supply the power supply voltage VDD at a current which is equal to or less than an allowable maximum current.

The ground channel 202 supplies the ground voltage GND through the ground input port 142 of the test board 100. The ground (or reference) voltage GND from the automatic test equipment 200a is applied to the ground input terminal 122 of the current limit circuit 120. The ground channel 202 may output the constant ground voltage. In an exemplary embodiment, the ground voltage may be 0 V. In another exemplary embodiment, the ground channel 202 may output a reference voltage, e.g., a predetermined positive or negative voltage.

The data input/output channel 203 is connected to the data terminal 18 of the semiconductor device under test 10 through the data input/output port 143 of the test board 100. The automatic test equipment 200a may output a test sequence for testing the semiconductor device under test 10 and receive data, which is output from the semiconductor device under test 10, through the data input/output channel 203.

For example, if the semiconductor device under test 10 is a DRAM, the automatic test equipment 200a may record a predetermined data pattern in all memory cells and read the data pattern back. The automatic test equipment 200a may transmit the predetermined data pattern and a command for recording the data pattern to the semiconductor device under test 10. The semiconductor device under test 10 may receive the command and data and execute the command. The automatic test equipment 200a may transmit a read command to the semiconductor device under test 10, and the semiconductor device under test 10 may output the data pattern stored therein.

In another exemplary embodiment, the semiconductor device under test 10 may include a test sequence in itself. The automatic test equipment 200a may command the semiconductor device under test 10 to execute the test sequence by itself. The semiconductor device under test 10 may receive the command, execute the test sequence by itself, and transmit a test result to the automatic test equipment 200a.

In an exemplary embodiment, if the test board 100a includes a plurality of current limit circuits 120, the power output channels 201 of the automatic test equipment 200a may be connected to the current limit circuits 120, respectively. In another exemplary embodiment, according to average current consumption and a peak current amplitude of the semiconductor device under test 10, the one power output channel 201 of the automatic test equipment 200a may supply the power supply voltage VDD to the current limit circuits 120. The power output channels 201 of the automatic test equipment 200a may also be connected to the one current limit circuit 120.

FIG. 3B is a schematic block diagram of one embodiment of a test system 1000b. The test system 1000b of FIG. 3B is a modification of the test system 1000a of FIG. 3A. The descriptions of the test system 1000a and the components 10, 100, 200a thereof in FIG. 3A may be applied to the test system 1000b of FIG. 3B.

Referring to FIG. 3B, the test system 1000b may include automatic test equipment 200b for testing the semiconductor device under test 10 and a test board 100b connecting the semiconductor device under test 10 and the automatic test equipment 200b to each other. The automatic test equipment 200b may output a test control signal TCS for setting conditions of the test board 100b for a test. The automatic test equipment 200b may output the test control signal TCS through a control signal output terminal 204. The test control signal TCS may be applied to a control signal input terminal 144 of the test board 100b.

A current limit circuit 120b may receive the test control signal TCS through a control signal input terminal 128 and may be operated based on the received test control signal TCS. For example, a determination may be made as to whether the current limit circuit 120b is operated based on a setting of the test control signal TCS. In one embodiment, the current limit circuit 120b may diversely adjust the maximum amount of current which may flow through the power pads 134 or the ground pads 136 based on a setting of the test control signal TCS.

FIG. 3C illustrates another embodiment of a test system 1000c which includes automatic test equipment 200c for testing the semiconductor device under test 10, a power supply 300 supplying power, and the test board 100 for connecting the semiconductor device under test 10, the automatic test equipment 200c, and power supply 300 to one another. The semiconductor device under test 10 and the test board 100 may correspond to one or more of the aforementioned embodiments.

The automatic test equipment 200c may include the ground channel 202 and the data input/output channel 203 without the power output channel 201, unlike the automatic test equipment 200a in FIG. 3A. The power supply voltage, which is supplied from the power output channel 201 of the automatic test equipment 200a in FIG. 3A, is provided by the power supply 300.

The power supply 300 may include an output terminal 301 and a ground terminal 302. The output terminal 301 may supply the power supply voltage VDD to the current limit circuit 120 through the power input terminal 141 of the test board 100. The ground terminal 302 may be connected in common to the ground channel 202 of the automatic test equipment 200c and the ground input port 142 of the test board 100. Thus, the power supply 300, the automatic test equipment 200c, the test board 100, and the semiconductor device under test 10 may have the same ground potential in at least one embodiment.

The automatic test equipment 200c is high-priced equipment having a plurality of channels for outputting voltages and currents according to a sequence, which, for example, may be preset by an operator. The voltages and currents output from the automatic test equipment 200c may have high or predetermined qualities. The automatic test equipment 200c may output electric power to test the semiconductor device under test 10 using one power output channel in order to test the one semiconductor device under test 10. For example, a maximum (or other predetermined) current output from the power output channel of the automatic test equipment 200c may be 1 A. In contrast, with increasing power consumption of the semiconductor device under test 10, current exceeding 1 A may be generated in the semiconductor device under test 10. Thus, to test the one semiconductor device under test 10, the power supply voltage of the semiconductor device under test 10 may also be supplied through the two or more power output channels.

The power supply 300 may be a direct current power supply outputting, for example, a constant voltage. Since the power supply 300 may be widely used in various fields, the power supply 300 may be lower in price than the automatic test equipment 200c. The test system 1000b may be configured using the low-priced power supply 300, instead of the high-priced automatic test equipment 200c to reduce test costs.

In an exemplary embodiment, the test board 100 may include a voltage regulator, may stabilize the power supply voltage from the power supply 300, and may provide the stabilized power supply voltage to the semiconductor device under test 10. In an exemplary embodiment, the voltage regulator and the current limit circuit 120 may be realized as one module or one semiconductor chip.

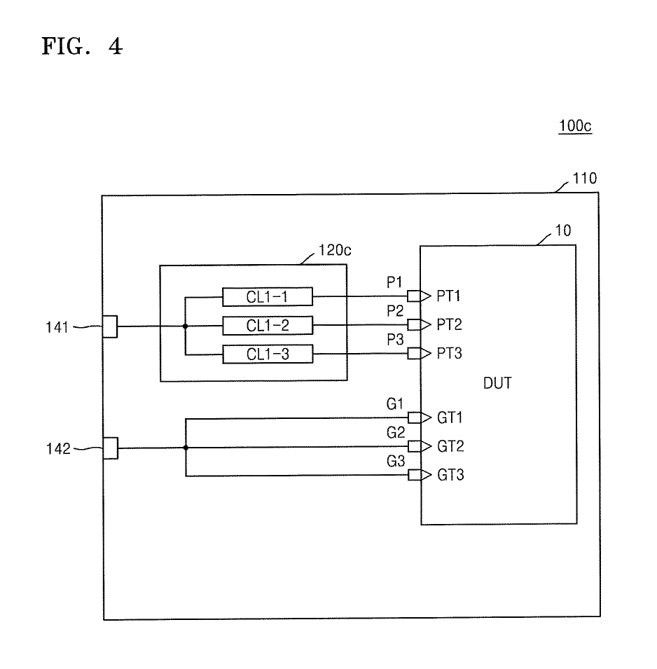

FIG. 4 illustrates an embodiment of a test board 100c which is a modification of the test board 100a in FIG. 2. In the present exemplary embodiment, the power supply voltage may be applied to the power input port 141 of the test board 100c and may be provided to a current limit circuit 120c. In addition, the ground voltage may be applied to the ground input port 142 of the test board 100c and may be provided to the ground pads G1 to G3. For example, the ground voltage may be provided to the ground pads G1 to G3, for example, through the ground plane 114 in FIG. 1.

The current limit circuit 120c may individually provide the power supply voltage to each of the power pads P1 to P3, and may limit the amount of current to be output through each of the power pads P1 to P3. For this purpose, the current limit circuit 120c may include the output current limiters CL1-1, CL1-2, CL1-3. The output current limiters CL1-1, CL1-2, CL1-3 may be electrically connected to the power pads P1 to P3 in a point-to-point manner, respectively. Each of the output current limiters CL1-1, CL1-2, CL1-3 may limit the amount of current output from a corresponding power pad.

As described above, the test board 100c according to the present exemplary embodiment limits the amount of current output from each of the power pads P1 to P3, thereby preventing generation of an unexpected large overcurrent.

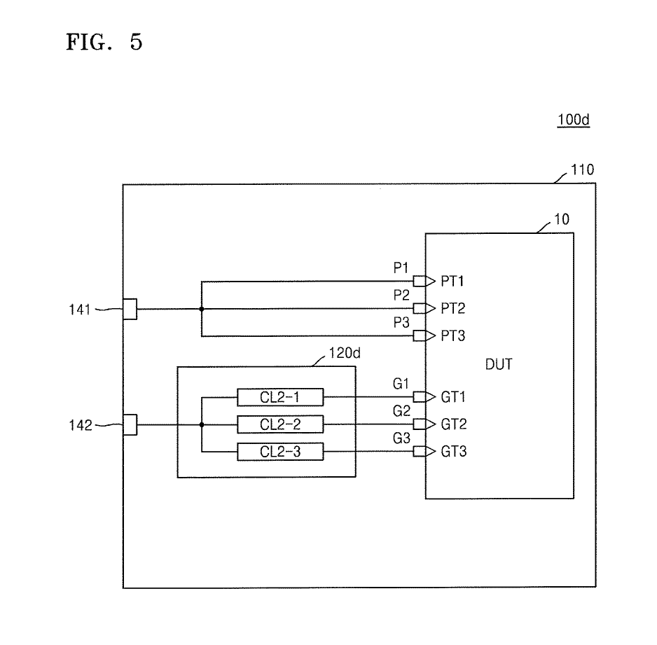

FIG. 5 illustrates an embodiment of a test board 100d which is a modification of the test board 100a in FIG. 2. In the present exemplary embodiment, the power supply voltage applied to the power input terminal 141 of the test board 100d may be provided to the power pads P1 to P3. The ground voltage applied to the ground input port 142 may be provided to a current limit circuit 120d. For example, the power supply voltage VDD may be provided to the power pads P1 to P3, for example, through the power plane 112 in FIG. 1.

The current limit circuit 120d may individually provide the ground voltage to each of the ground pads G1 to G3 and may limit the amount of current which is input through each of the ground pads G1 to G3. For this purpose, the current limit circuit 120d may include a plurality of input current limiters CL2-1, CL2-2, CL2-3. The input current limiters CL2-1, CL2-2, CL2-3 may be electrically connected to the ground pads G1 to G3 in a point-to-point manner, respectively. Each of the input current limiters CL2-1, CL2-2, CL2-3 may limit the amount of inflowing current through a corresponding ground pad.

As described above, the test board 100d according to the present exemplary embodiment limits the current input from each of the ground pads G1 to G3, thereby preventing generation of an unexpected large overcurrent.

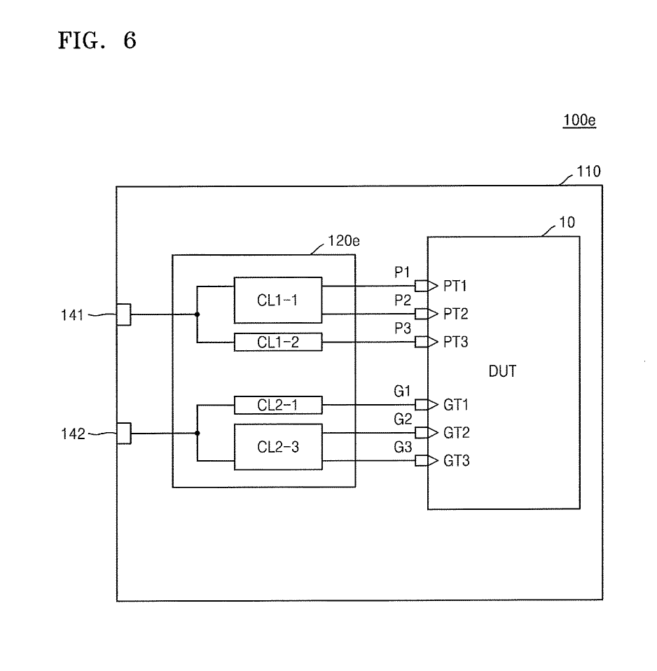

FIG. 6 illustrates another embodiment of a test board 100e which is a modification of the test board 100a in FIG. 2. Referring to FIG. 6, a current limit circuit 120e may include a plurality of output current limiters CL1-1, CL1-2 and a plurality of input current limiters CL2-1, CL2-2. Here, the first output current limiter CL1-1 may be connected to the first and second power pads P1, P2 to limit amounts of current flowing through the first and second power pads P1, P2. The second output current limiter CL1-2 may be connected to the third power pad P3 to individually limit the amount of current flowing through the third power pad P3. The first input current limiter CL2-1 may be connected to the first ground pad G1 to individually limit an amount of current flowing through the first ground pad G1. The second input current limiter CL2-2 may be connected to the second and third ground pads G2, G3 to limit amounts of current flowing through the second and third ground pads G2, G3.

The third power pad P3 and the first ground pad G1 are arranged in contiguity with each other. The third power pad P3 and the first ground pad G1, which are contiguously arranged, are more likely to be short-circuited to each other than the other power pads P1, P2 and the other ground pads G2, G3. In the test board 100e according to the present exemplary embodiment, the current limit circuit 120e may individually control the amounts of current flowing through the power pad and the ground pad which are contiguous. The amounts of current, which flow through the power pads not contiguous to the ground pads (e.g., the first and second power pads P1, P2) or through the ground pads not contiguous to the power pads (e.g., the second and third ground pads G2, G3) may be controlled in units of the plurality of pads. Thus, generation of a large amount of unexpected overcurrent may be prevented and the area of the current limit circuit 120e may be reduced.

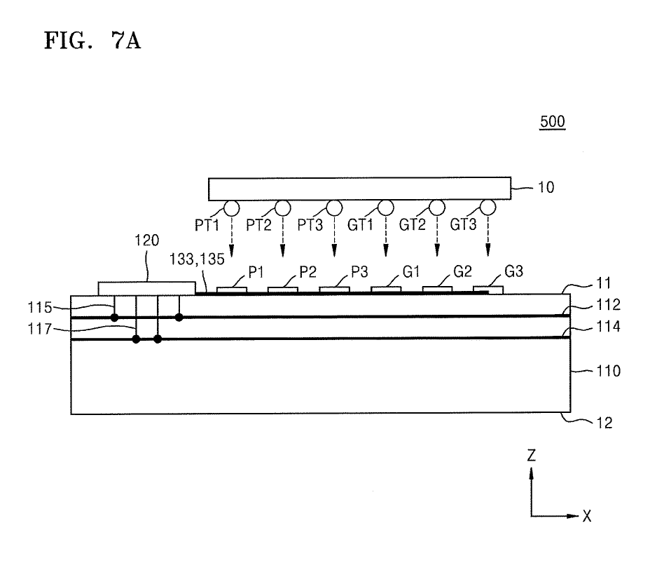

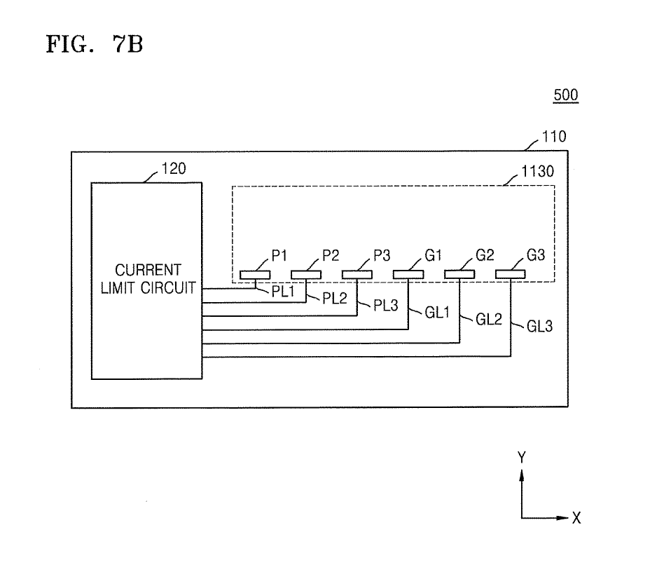

FIG. 7A is a vertical sectional view of another embodiment of a test board 500 and FIG. 7B is a plan view of the test board in FIG. 7A. The semiconductor device under test 10 is shown together for convenience. FIG. 7A is a sectional view for the perspective view of FIG. 1 based on an X-Z plane, and FIG. 7B is a top view for the perspective view of FIG. 1 based on an X-Y plane.

First, referring to FIG. 7A, a test board 500 may include the substrate 110, the plurality of power pads P1 to P3, the plurality of ground pads G1 to G3, and the current limit circuit 120. The power plane 112 and the ground plane 114 may be arranged in the substrate 110. The power pads P1 to P3 and the ground pads G1 to G3 may be arranged on a first surface 11 of the substrate 110. The connector 140 in FIG. 1 may be arranged on the first surface 11 or a second surface 12 of the substrate 110 and may be connected to the power plane 112 and the ground plane 114.

The current limit circuit 120 may be realized as at least one semiconductor chip or module, and may be arranged on the first surface 11 of the substrate 110. The current limit circuit 120 may be connected to the power plane 112 and the ground plane 114 through vertical wiring lines 115, 117. The vertical wiring lines 115, 117 may include, for example, via contact plugs penetrating through the insulating layers and the conductive layer among the power plane 112, the ground plane 114, and the current limit circuit 120.

The current limit circuit 120 may receive the power supply voltage and the ground voltage from the power plane 112 and the ground plane 114, and may provide the power supply voltage and the ground voltage to the power pads P1 to P3 and the ground pads G1 to G3 through the individual power and ground lines 133, 135, respectively.

Referring to FIG. 7B, the current limit circuit 120 may be connected to the power pads P1 to P3 through the power lines PL1 to PL3, and may be connected to the ground pads G1 to G3 through the ground lines GL1 to GL3. Here, the current limit circuit 120 may limit the amount of current flowing through each of the power lines PL1 to PL3 and the ground lines GL1 to GL3.

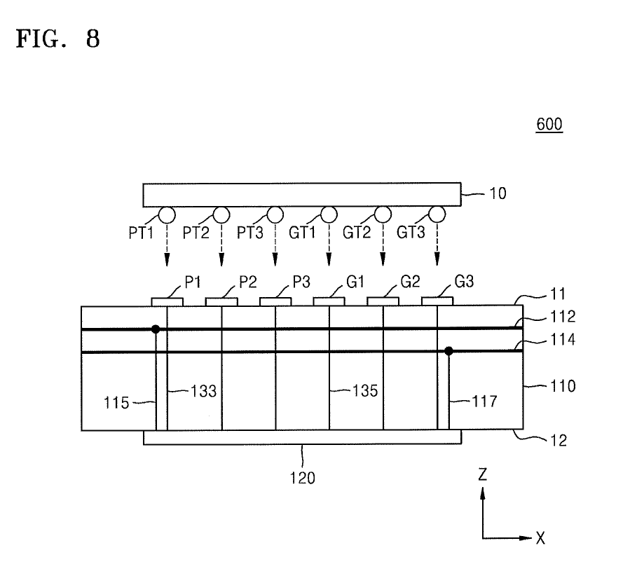

FIG. 8 illustrates a vertical sectional view of another embodiment of a test board 600. The semiconductor device under test 10 is shown together for convenience.

Referring to FIG. 8, a test board 600 may include the substrate 110, the plurality of power pads P1 to P3, the plurality of ground pads G1 to G3, and the current limit circuit 120. The power plane 112 and the ground plane 114 may be arranged in the substrate 110. The power pads P1 to P3 and the ground pads G1 to G3 may be arranged on the first surface 11 of the substrate 110.

The current limit circuit 120 may be realized as at least one semiconductor chip or module and may be arranged on the second surface 12 of the substrate 110. The current limit circuit 120 may be connected to the power plane 112 and the ground plane 114 through vertical wiring lines 115, 117. The current limit circuit 120 may be connected to the power pads P1 to P3 through the power lines 133 and may be connected to the ground pads G1 to G3 through the ground lines 135. The power lines 133 and the ground lines 135 may include via contact plugs penetrating through the insulating layers and the conductive layer in the board.

In the test board 600 according to the present exemplary embodiment, the current limit circuit 120 may be arranged on the second surface 12 opposite to the first surface 11 of the substrate 110 on which the pads P1 to P3, G1 to G3 are arranged. The current limit circuit 120 may be connected to the pads P1 to P3, G1 to G3 through the power lines 133 and the ground lines 135, which penetrate through the substrate 110. Thus, since there is no need for additional regions for the wiring lines and the current limit circuit 120 on the first surface 11 of the substrate 110, the area of the test board 600 may be reduced.

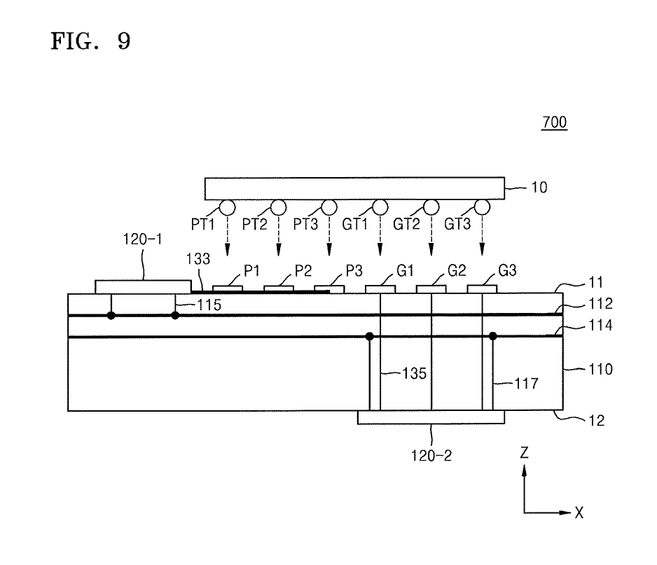

FIG. 9 illustrates a vertical sectional view of another embodiment of a test board 700. The semiconductor device under test 10 is shown together for convenience.

Referring to FIG. 9, the test board 700 may include the substrate 110, the plurality of power pads P1 to P3, the plurality of ground pads G1 to G3, a first current limit circuit 120-1, and a second current limit circuit 120-2. The power plane 112 and the ground plane 114 may be arranged in the substrate 110. The power pads P1 to P3 and the ground pads G1 to G3 may be arranged on the first surface 11 of the substrate 110.

The first current limit circuit 130-1 may be arranged on the first surface 11 of the substrate 110. The first current limit circuit 130-1 may include the current limit circuit 120c of FIG. 4. The first current limit circuit 130-1 may be connected to the power plane 112 through at least one first vertical wiring line 115. The first current limit circuit 130-1 may receive the power supply voltage from the power plane 112, and may provide the power supply voltage to the power pads P1 to P3 through the power lines 133, respectively.

The second current limit circuit 130-2 may be arranged on the second surface 12 of the substrate 110. The second current limit circuit 130-2 may include, for example, the current limit circuit 120d of FIG. 5. The second current limit circuit 130-2 may be connected to the ground plane 114 through at least one second vertical wiring line 117. The second current limit circuit 130-2 may be connected to the ground plane 114, through the at least one second vertical wiring line 117, to receive the ground voltage from the ground plane 114. The second current limit circuit 130-2 may be connected to the ground pads G1 to G3 through the ground lines 135, which penetrate through the substrate 110 to individually provide the ground voltage to the ground pads G1 to G3.

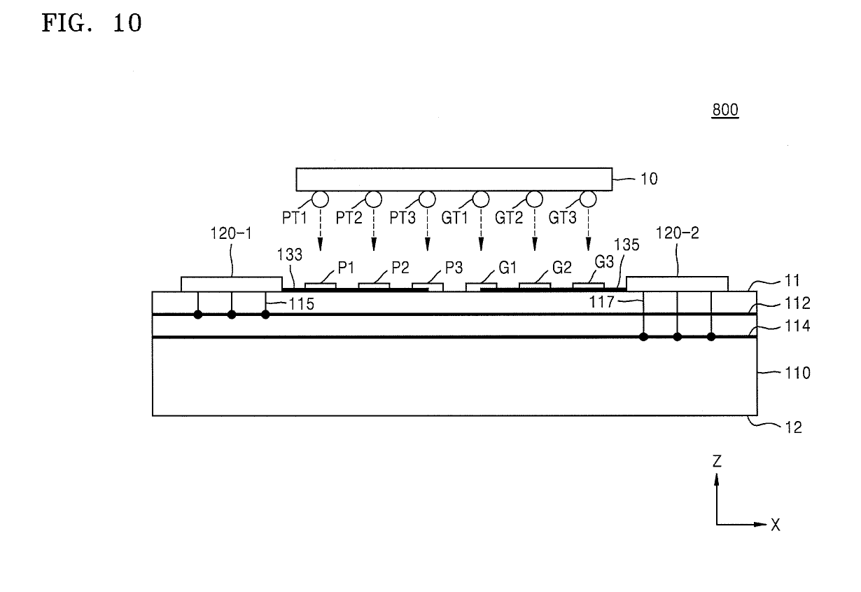

FIG. 10 illustrates a vertical sectional view of another embodiment of a test board 800. Referring to FIG. 10, the test board 800 may include the substrate 110, the plurality of power pads P1 to P3, the plurality of ground pads G1 to G3, the first current limit circuit 120-1, and the second current limit circuit 120-2. The first current limit circuit 120-1 and the second current limit circuit 120-2 may be realized, for example, as semiconductor chips or modules different from each other. The semiconductor device under test 10 is shown for convenience.

The power plane 112 and the ground plane 114 may be arranged in the substrate 110. The power pads P1 to P3 and the ground pads G1 to G3 may be arranged on the first surface 11 of the substrate 110.

The first current limit circuit 120-1 may be arranged on the first surface 11 of the substrate 110. The first current limit circuit 120-1 may include, for example, the current limit circuit 120c of FIG. 4. The first current limit circuit 120-1 may be connected to the power plane 112 through the at least one first vertical wiring line 115. The first current limit circuit 120-1 may receive the power supply voltage from the power plane 112 and may provide the power supply voltage to the power pads P1 to P3 through the power lines 133, respectively.

The second current limit circuit 120-2 may also be arranged on the first surface 11 of the substrate 110. The second current limit circuit 120-2 may include, for example, the current limit circuit 120d of FIG. 5. The second current limit circuit 120-2 may be connected to the ground plane 114 through the at least one second vertical wiring line 117. The second current limit circuit 120-2 may receive the ground voltage from the ground plane 114 and may provide the ground voltage to the ground pads G1 to G3 through the ground lines 135, respectively.

In FIG. 10, the second current limit circuit 120-2 is arranged on an opposite side of the first current limit circuit 120-1 relative to the power pads P1 to P3 and the ground pads G1 to G3, e.g., relative to the connection region. In another embodiment, the first current limit circuit 130-1 and the second current limit circuit 130-2 may be arranged at other locations on the first surface 11 of the substrate 110 relative to the power pads P1 to P3 and the ground pads G1 to G3.

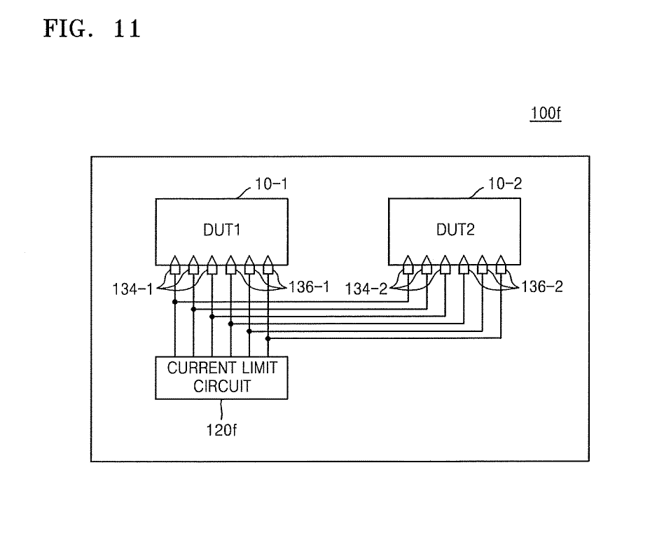

FIG. 11 illustrates another embodiment of a test board 100f which may test a plurality of semiconductor devices under test 10-1, 10-2. One current limit circuit 120f may limit the amount of current flowing through the power terminal or the ground terminal of the semiconductor devices under test 10-1, 10-2.

The current limit circuit 120f may be connected to power pads 134-1 and ground pads 136-1, which are respectively connected to the power terminals and the ground terminals of the first semiconductor device under test 10-1. The current limit circuit 120f may also be connected to power pads 134-2 and ground pads 136-2, which are respectively connected to the power terminals and the ground terminals of the second semiconductor device under test 10-2. The current limit circuit 120f may include, for example, the current limiters CL in FIG. 2. The current limiters CL may be connected to the power pads 134-1 and the ground pads 136-1, respectively. The current limiters CL may also be connected to the power pads 134-2 and the ground pads 136-2, respectively.

In an exemplary embodiment, the semiconductor devices under test 10-1, 10-2 may be sequentially tested. During a period of time of testing the first semiconductor device under test 10-1, the current limit circuit 120f may limit currents flowing through the power pads 134-1 and the ground pads 136-1, while providing the power supply voltage and the ground voltage to the power pads 134-1 and the ground pads 136-1. During a period of time of testing the second semiconductor device under test 10-2, the current limit circuit 120f may limit currents flowing through the power pads 134-2 and the ground pads 136-2, while providing the power supply voltage and the ground voltage to the power pads 134-2 and the ground pads 136-2.

The test board 100f allows one current limit circuit 120f to be used to test the plurality of semiconductor devices under test 10-1, 10-2, thereby reducing the area of the test board 100f and reducing test costs.

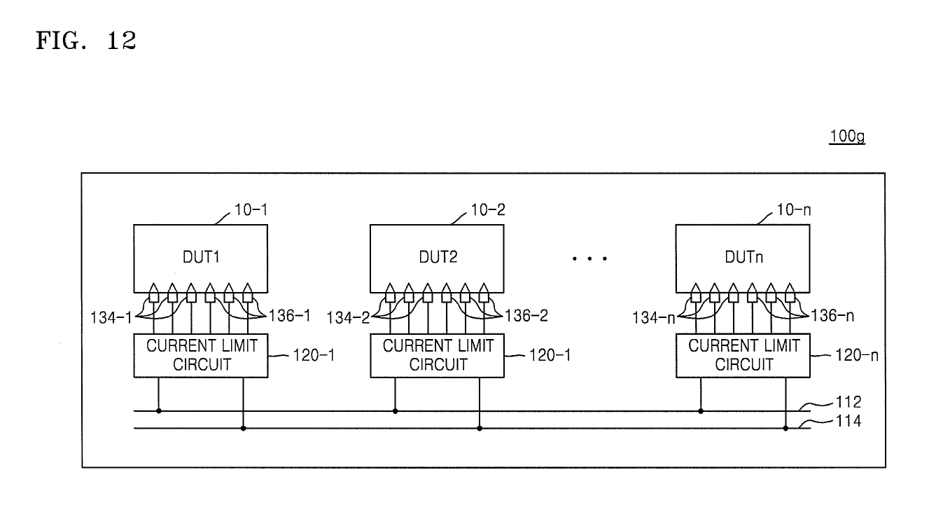

FIG. 12 illustrates another embodiment of a test board 100g which may test the plurality of semiconductor devices under test 10-1, 10-2, . . . 10-n. Although n semiconductor devices are shown as being tested, the test board 100 may test a different number of semiconductor devices in another embodiment.

The test board 100g may include the n semiconductor devices under test 10-1, 10-2, . . . , 10-n, and n current limit circuits 120-1, 120-2, . . . , 120-n corresponding to the n semiconductor devices under test 10-1, 10-2, . . . , 10-n. In addition, the test board 100g may include the power plane 112 providing the power supply voltage to the n current limit circuits 120-1, 120-2, . . . , 120-n, and the ground plane 114 providing the ground voltage to the n current limit circuits 120-1, 120-2, . . . , 120-n. As described above with reference to FIGS. 7A to 10, the n current limit circuits 120-1, 120-2, . . . , 120-n may be supplied with the power supply voltage and the ground voltage from the power plane 112 and the ground plane 114 through the vertical wiring lines.

While providing the power supply voltage to a plurality of power pads 134-1, 134-2, . . . , 134-n through the plurality of power lines, the n current limit circuits 120-1, 120-2, . . . , 120-n may control amounts of current flowing through the power lines, respectively. In addition, while providing the ground voltage to a plurality of ground pads 136-1, 136-2, . . . , 136-n through the ground lines, then current limit circuits 120-1, 120-2, . . . , 120-n may control amounts of current flowing through the ground lines, respectively. Thus, the n current limit circuits 120-1, 120-2, . . . , 120-n may prevent generation of unexpected large overcurrents in the power terminals and the ground terminals of the n semiconductor devices under test 10-1, 10-2, . . . , 10-n, respectively.

Because the test board 100g includes the n current limit circuits 120-1, 120-2, . . . , 120-n corresponding to the n semiconductor devices under test 10-1, 10-2, . . . , 10-n, the test board 100g may simultaneously test n semiconductor devices under test 10-1, 10-2, . . . , 10-n to reduce test time.

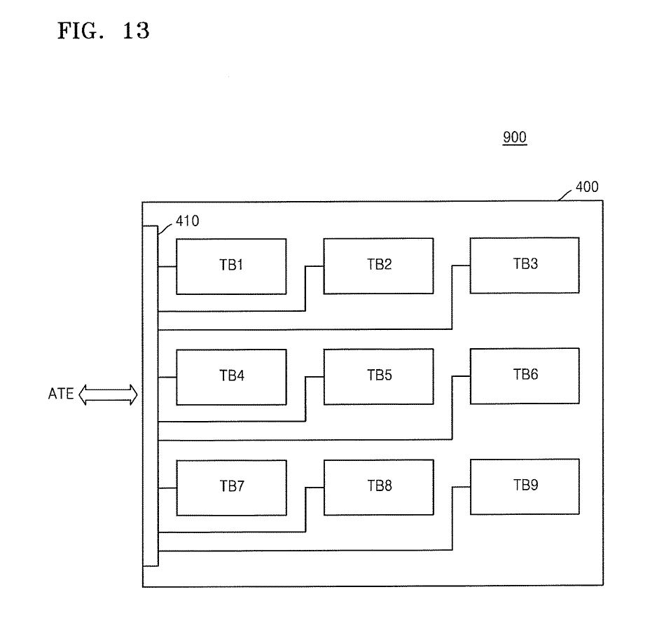

FIG. 13 illustrates an embodiment of a test apparatus 900 which may include a test head 400, an interface unit 410, and a plurality of test boards TB1 to TB9. The test boards TB1 to TB9 may be, for example, any of the test boards corresponding to FIGS. 1, 2, and 4 to 12.

The test head 400 may have a plurality of mounting portions, and the test boards TB1 to TB9 may be mounted on the mounting portions, respectively. The test boards TB1 to TB9 may be separated from the test head 400, and test boards corresponding to specifications of the semiconductor devices under test may be arranged in the test head 400, instead of the test boards TB1 to TB9. The nine test boards TB1 to TB9 are shown as being arranged in a matrix form in FIG. 13 for convenience. The number and/or arrangement of the test boards may be different in other embodiments according to, for example, the test environment.

The test head 400 may include a power supply supplying driving power to the test boards TB1 to TB9 and a cooler discharging heat generated during a test to a location outside of the test head 400.

The interface unit 410 may communicate with the automatic test equipment ATE, receive data according to a test sequence from the automatic test equipment ATE, and provide data, which is output from the test boards TB1 to TB9, to the automatic test equipment ATE. In addition, the interface unit 410 may collect test situations or test results of the semiconductor devices under test, which are mounted on the test boards TB1 to TB9 to be tested, and may provide data according to the collected results to the automatic test equipment ATE.

The test apparatus 900 according to the present exemplary embodiment may simultaneously test a large number of the semiconductor devices under test through the test boards TB1 to TB9 mounted on the test head 400. The test boards TB1 to TB9 limit amounts of current flowing through the power terminals and the ground terminals of the semiconductor devices under test using the current limit circuits, respectively. As a result, damage of the semiconductor device under test may be prevented when contact between the semiconductor device under test and the test board is unstable. Thus, the test apparatus 900 may quickly perform inspection of a large number of the semiconductor devices under test and may improve test reliability.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods herein.

The test equipment, current limiters, and other processing features of the embodiments disclosed herein may be implemented in logic which, for example, may include hardware, software, or both. When implemented at least partially in hardware, the test equipment, current limiters, and other processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the test equipment, current limiters, and other processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods herein.

By way of summation and review, a power plane and a ground plane have commonly provided a power supply voltage and a ground voltage supplied from automatic test equipment (ATE) to a plurality of power terminals and a plurality of ground terminals of a device under test (DUT). As semiconductor devices operating at high speeds come to the forefront, the pitch between input/output terminals (for example, solder balls) of a package of the semiconductor device decreases. If contact between a power/ground terminal of the package and a power/ground terminal of a test board is poor and a short occurs between a power terminal and a ground terminal, a large amount current flows and a solder ball or other connection of the package may melt.

In accordance with one or more of the aforementioned embodiments, a test board includes a current limit circuit (or current limit array) individually providing a power supply voltage and a ground voltage to power and ground terminals of a DUT. The current limit circuit includes a plurality of current limiters connected in a point-to-point manner to power pads and ground pads of the test board, which are connected to the power terminals and the ground terminals of the DUT, respectively.

Using the plurality of current limiters, the current limit circuit (or current limit array) separates the power supply voltage and the ground voltage supplied from ATE by as much as the number of the power and ground terminals of the DUT. The current limit circuit or array limits the amount of current flowing through each of the power and ground terminals of the DUT, while individually providing the power supply voltage and the ground voltage to the power and ground terminals of the DUT. As a result, damage to the power and ground terminals may be prevented if a short circuit forms.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the embodiments set forth in the claims.

What is claimed is:

1. A test board, comprising:
a substrate;
a plurality of power pads on the substrate, the power pads to output a power supply voltage to a plurality of power terminals of a semiconductor device under test; and
a current limit circuit to limit a current flowing through each of the power pads.

2. The test board as claimed in claim 1, wherein the current limit circuit is to:
provide the power supply voltage individually to the power pads through a plurality of power lines respectively connected to the power pads, and
limit current flowing through each of the power lines.

3. The test board as claimed in claim 1, wherein the current limit circuit includes a plurality of current limiters connected to the power pads in a point-to-point manner.

4. The test board as claimed in claim 1, further comprising:
a plurality of ground pads on the substrate, the ground pads to output a ground voltage to the semiconductor device under test, wherein the current limit circuit is to limit a current flowing through each of the power pads and each of the ground pads.

5. The test board as claimed in claim 4, wherein the current limit circuit includes:
a first current limit unit including a plurality of first current limiters respectively connected to the power pads; and
a second current limit unit including a plurality of second current limiters respectively connected to the ground pads.

6. The test board as claimed in claim 1, further comprising:
a power plane in the substrate,
wherein the current limit circuit is to electrically connect the power pads to the power plane.

7. The test board as claimed in claim 1, wherein the power pads and the current limit circuit are arranged on a first surface of the substrate.

8. The test board as claimed in claim 1, wherein:
the power pads are on a first surface of the substrate,
the current limit circuit is on a second surface different from the first surface of the substrate, and
the current limit circuit and the power pads are connected to each other through a through wiring line penetrating through the substrate.

9. The test board as claimed in claim 1, further comprising:
a connector to receive the power supply voltage from test equipment external to the test board and to provide the power supply voltage to the current limit circuit.

10. The test board as claimed in claim 1, wherein:
the semiconductor device under test is a semiconductor package including a semiconductor circuit, and
at least one socket, onto which the semiconductor package is loaded, is mounted on the test board.

11. A test system, comprising:
test equipment to test a semiconductor device under test; and
a test board connected between the semiconductor device under test and the test equipment, wherein the test board includes a plurality of power pads electrically connected to the semiconductor device under test and wherein the test board is to individually provide at least one power supply voltage, which is supplied from the test equipment, to the power pads through a plurality of power lines and is to limit currents flowing through the power pads.

12. The test system as claimed in claim 11, wherein the test board includes a current control circuit which includes a plurality of current controllers respectively connected to the power pads.

13. The test system as claimed in claim 12, wherein the test board includes:
a plurality of power lines respectively connecting the current controllers to the power pads in a point-to-point manner, wherein each of the current controllers is to limit a maximum current flowing through a corresponding one of the power lines.

14. The test system as claimed in claim 12, further comprising:
a connector to receive the at least one power supply voltage from the test equipment; and
a power plane connected to the connector to provide the power supply voltage to each of the power pads through the current control circuit.

15. The test system as claimed in claim 11, wherein the semiconductor device under test is a semiconductor device having a high-speed data input/output terminal.

16. An apparatus, comprising:
a plurality of power pads to output a power supply voltage to a plurality of power terminals of a semiconductor device under test; and
a current limit circuit to provide the power supply voltage individually to the power pads through a respective plurality of power lines connected to the power pads and to limit current flowing through each of the power lines.

17. The apparatus as claimed in claim 16, wherein the current limit circuit includes a plurality of current limiters connected to the power pads in a point-to-point manner.

18. The apparatus as claimed in claim 16, wherein the current limit circuit includes:
a first current limit unit including a plurality of first current limiters respectively connected to the power pads; and
a second current limit unit including a plurality of second current limiters respectively connected to the ground pads.
